(19) United States
(12) Patent Application Publication
(10) Pub. No.: US 2026/0077633 A1
(43) Pub. Date: Mar. 19, 2026

(54) HEAT MEDIUM HEATING APPARATUS

(71) Applicant: Niterra Co., Ltd., Nagoya-shi (JP)

(72) Inventor: Hiroki HATTORI, Nagoya-shi (JP)

(21) Appl. No.: 19/272,527

(22) Filed: Jul. 17, 2025

(30) Foreign Application Priority Data
Jul. 23, 2024 (JP) 2024-117538

(51) Int. Cl. B60H 1/22; H05K 7/20

(52) U.S. Cl. CPC B60H 1/2221; H05K 7/20854; B60H 2001/224

(57) ABSTRACT

A heat medium heating apparatus includes: a circuit board; an electronic component disposed on the circuit board; a flow channel member formed of a metal and having a flow channel through which a heat medium flows; and a heater which is disposed in the flow channel and heats the heat medium. A heat sink portion is formed integrally with the flow channel member. The heat sink portion is connected to an outer boundary of the flow channel and has a surface on which the electronic component is mounted.

### TECHNICAL FIELD

The present invention relates to a heat medium heating apparatus.

### BACKGROUND ART

JP2018-133300A (Patent Document 1 listed below) discloses a conventionally known heat medium heating apparatus used for a vehicle air conditioner. This heat medium heating apparatus includes a casing in which a heat medium flows, a PTC (positive temperature coefficient) heater for heating the heat medium, and a control board for controlling the PTC heater. The casing has a board housing portion for housing the control board. The control board has electronic components. Patent Document 1 describes that heat-generating electronic components such as an IGBT (insulated gate bipolar transistor) and an FET (field effect transistor), and electronic components other than the heat-generating electronic components can be used as the electronic components of the control board.

### PRIOR ART DOCUMENT

### Patent Document

[Patent Document 1] Japanese Patent Application Laid-Open (kokai) No. 2018-133300

### SUMMARY OF THE INVENTION

### Problem to be Solved by the Invention

In the above-described configuration, the electronic components are disposed in a space inside the board housing portion and are not in contact with members other than the board main body of the control board. In the case where a heat-generating electronic component is used, heat generated from the electronic component is transferred to the air within the board housing portion. In such a case, heat is not sufficiently radiated from the electronic component, and the electronic component is overheated, whereby the electronic component may fail to function normally.

The present invention has been completed based on the above circumstances, and an object of the present invention is to provide a heat medium heating apparatus which can increase the efficiency of heat radiation from a heat-generating electronic component.

### Means for Solving the Problem

A heat medium heating apparatus of the present invention is a heat medium heating apparatus comprising: a circuit board; an electronic component disposed on the circuit board; a flow channel member formed of a metal and having a flow channel through which a heat medium flows; and a heater which is disposed in the flow channel and heats the heat medium, wherein a heat sink portion is formed integrally with the flow channel member, the heat sink portion being connected to an outer boundary of the flow channel and having a surface on which the electronic component is mounted.

By virtue of such a configuration, the heat generated by the electronic component can be transferred from the heat sink portion to the heat medium in the flow channel, whereby the efficiency of heat radiation from the electronic component can be increased.

In the heat medium heating apparatus of the present invention, the flow channel may have a circular cross section, and the heat sink portion may be connected to the tubular outer boundary of the flow channel.

By virtue of such a configuration, since the flow channel has a circular cross section, the heat medium can smoothly flow through the flow channel. In addition, since the heat sink portion is connected to the outer boundary of the flow channel such that the heat sink portion constitutes a portion of the outer boundary, the height (distance) of the heat sink portion from the flow channel can be reduced, whereby the size of the heat medium heating apparatus can be reduced. In addition, the area of contact between the heat sink portion and the flow channel can be increased.

In the heat medium heating apparatus of the present invention, the flow channel may have a tubular shape and may extend in a longitudinal direction, and the flow channel may increase in diameter toward a side in the longitudinal direction toward which the heat medium flows.

By virtue of such a configuration, air bubbles produced in the heat medium as a result of heating by the heater become more likely to flow in the flow direction and be discharged to the outside from a diameter increased portion of the flow channel. As a result, it is possible to prevent the air bubbles from staying in the flow channel, which would otherwise result in heating by the heater with no liquid.

In the heat medium heating apparatus of the present invention, the heater may extend in an axial direction and may have a through hole along the axial direction, the heat medium introduced into the through hole through its one end flows out to an outer surface side of the heater through the other end of the through hole, reverses its flow direction at an inner wall surface of the flow channel, and flows along an outer surface of the heater toward an opposite side in the axial direction, and a corner portion of the inner wall surface of the flow channel, which corner portion faces the other end of the through hole, may be curved.

By virtue of such a configuration, when, after having flowed out to the outer surface side of the heater from the other end side of the through hole, the heat medium reverses its flow direction at the inner wall surface of the flow channel, the heat medium smoothly flows along the curved corner portion, whereby the efficiency of heat radiation from the electronic components via the heat medium can be further increased.

In the heat medium heating apparatus of the present invention, the heater may have a circular cross section.

By virtue of such a configuration, the heat medium smoothly flows along the outer surface of the heater, and thus, the efficiency of heat radiation from the electronic components via the heat medium cab be further increased.

### Effects of the Invention

The present invention makes it possible to provide a heat medium heating apparatus which can increase the efficiency of heat radiation from a heat-generating electronic component.

### BRIEF DESCRIPTION OF THE DRAWINGS

FIG. 1 is an exploded perspective view of a heat medium heating apparatus according to an embodiment of the present invention.

FIG. 2 is a perspective view of the heat medium heating apparatus.

FIG. 3 is a sectional view along line A-A in FIG. 2.

FIG. 4 is a cross-sectional view of a flow channel, taken perpendicularly to the sheet of FIG. 3.

### MODE FOR CARRYING OUT THE INVENTION

Hereinafter, an embodiment of the present invention will be described.

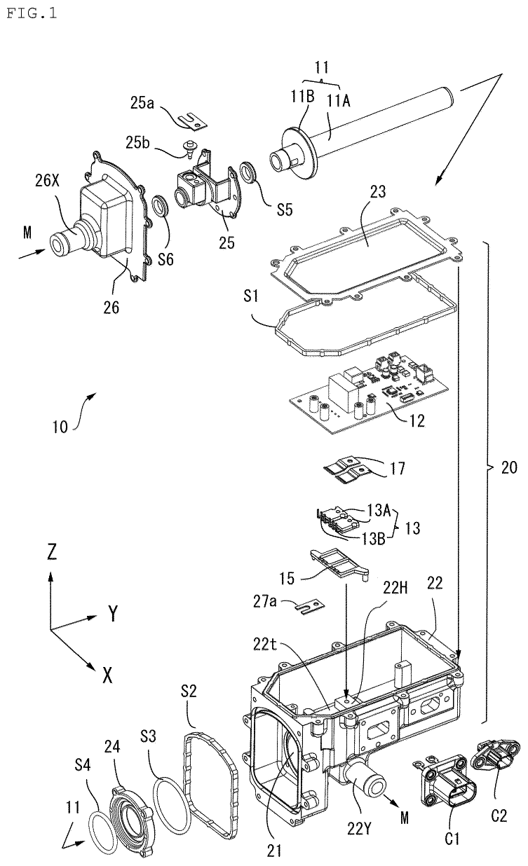

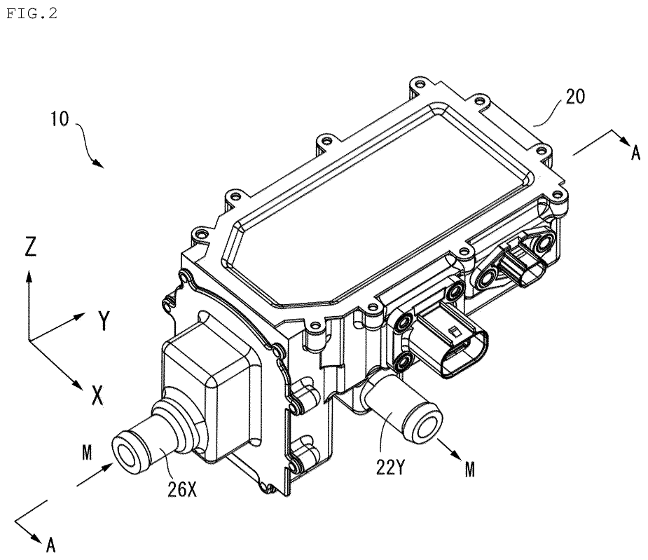

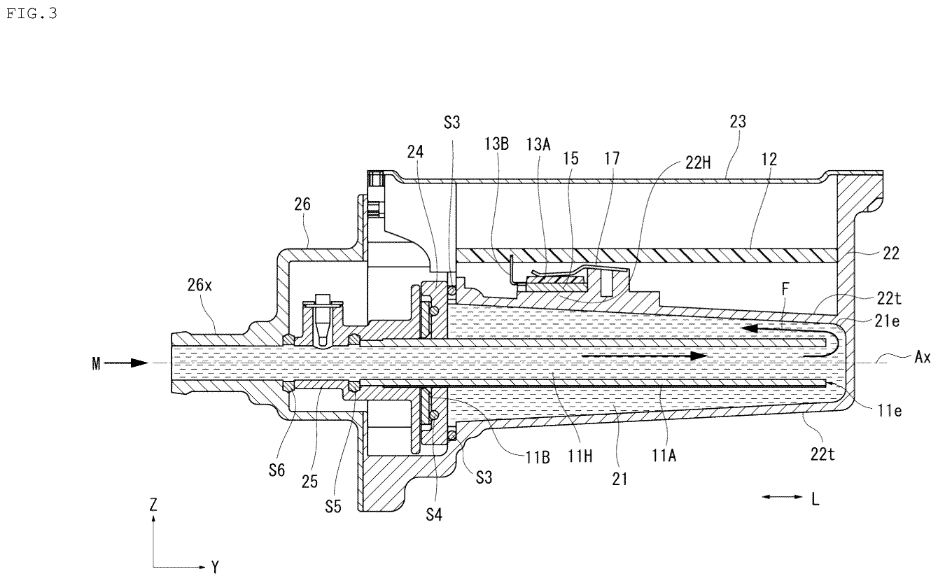

FIG. 1 is an exploded perspective view of a heat medium heating apparatus according to an embodiment of the present invention. FIG. 2 is a perspective view of the heat medium heating apparatus. FIG. 3 is a sectional view along line A-A in FIG. 2.

Notably, the present invention is not limited to these illustrative examples, and it is intended that the present invention is shown by the claims and encompasses all modifications within the meaning and scope equivalent to the claims. In the following description, as to a plurality of identical members, only some members are denoted by reference numerals and the remaining members are not denoted by the reference numerals in some cases.

In the present specification, for description of the structure of the heat medium heating apparatus 10, a Z-axis positive direction is defined as the upward direction, a Z-axis negative direction is defined as the downward direction, an X-axis positive direction is defined as the forward direction, and a Y-axis positive direction is defined as the rightward direction. However, in an actual use, the heat medium heating apparatus 10 may be disposed in an orientation different from the orientation shown in the drawings so that the directions associated with heat medium heating apparatus 10 differ from the defined directions.

The heat medium heating apparatus 10 according to the present invention heats a liquid (one example of the heat medium) such as water. The heat medium heating apparatus 10 is disposed in, for example, an electric vehicle (EV) and is used to heat the cabin of the electric vehicle or keep a battery warm.

As shown in FIG. 1, the heat medium heating apparatus 10 includes a heater 11, a circuit board 12, and casing 20 which houses the heater 11 and the circuit board 12.

The casing 20 includes a flow channel member 22 and various members 24 to 26 (which will be described later) attached to the flow channel member 22. A flow channel 21 is formed in the flow channel member 22. A heat medium M flows through the flow channel 21 and is heated by the heater 11 disposed in the flow channel 21.

In the present example, the heater 11 is a ceramic heater. The heater 11 includes a circular tubular member 11A and a heating resistor element (not shown) embedded in the circular tubular member 11A.

The circular tubular member 11A is formed mainly of a ceramic material such as alumina. The heating resistor element is formed of a metal such as tungsten and has the shape of a meandering thin wire. The heating resistor element generates heat when a voltage is applied thereto by a power supply.

The heater 11 can be manufactured by, for example, sandwiching a metal sheet of a predetermined pattern, which is to become the heating resistor element, between ceramic green sheets, winding the resultant laminate around a rod-shaped die member, and firing the laminate. The heater 11 has a flange portion 11B brazed to the outer circumferential surface of the circular tubular member 11A. The flange portion 11B has an annular plate-like shape. The flange portion 11B is disposed at a position near the left end of the circular tubular member 11A.

As shown in FIG. 1, electronic components 13 for controlling the output of the heater 11 are disposed on one surface (lower surface) of the circuit board 12. Each of the electronic components 13 is, for example, a switching element such as an FET, an IGBT, or the like. The electronic components 13 have characteristics which are likely to cause heat generation and generate heat when energized although the amount of generated heat is smaller than that of the heater 11.

Each electronic component 13 has a main body portion 13A and leads 13B electrically connected to the circuit board 12. The main body portion 13A is formed of a resin, and a semiconductor device or the like is embedded in the main body portion 13A. The leads 13B are disposed on a side surface of the main body portion 13A. Notably, the leads 13B may be disposed on the upper surface (the surface which faces the circuit board 12) of the main body portion 13A.

Although not shown in detail, lead wires connected to the heater 11 and various wires are electrically connected to the circuit board 12. These wires are electrically connected to an external power supply, etc. through external connectors C1 and C2. Notably, the external connectors C1 and C2 are attached to a side surface (on the positive direction side in the X-axis of FIG. 1) of the flow channel member 22.

As shown in FIG. 1, the casing 20 includes a flow channel member 22 and various members 24 to 26 attached to the flow channel member 22.

The flow channel member 22 has a generally box-like shape and has a tube portion 22t (see FIG. 3) integrally formed on the lower side of the flow channel member 22. The tube portion 22t has a circular cross section and defines the outer boundary of the flow channel 21. The heater 11 is disposed inside the tube portion 22t. The gap between the tube portion 22t and the heater 11 serves as the flow channel 21.

The tube portion 22t is open on the forward side (on the leftward direction side in the Y-axis of FIG. 1). A discharge port 22Y, which is an end portion of the flow channel 21, is integrally formed with the tube portion 22t in such a manner that the discharge port 22Y protrudes from one side surface of the tube portion 22t (on the positive direction side in the X-axis of FIG. 1).

The flow channel member 22 is formed of a metal and can be formed by, for example, aluminum die casting.

On the outer surface of the tube portion 22t, a heat sink portion 22H having a flat surface is integrally connected to the tube portion 22t. The flat surface (upper surface) of the heat sink portion 22H serves as a mounting surface for the electronic components 13.

The circuit board 12 is housed in an internal space of the flow channel member 22 located on the upper side of the tube portion 22t. The main body portions 13A of the electronic components 13 (in the present example, two electronic components) mounted on the lower surface of the circuit board 12 are in contact with the flat surface (upper surface) of the heat sink portion 22H.

Notably, in the present example, a resin-made insulating sheet (not shown) and a resin-made holder 15 for holding the electronic components 13 are interposed between the main body portions 13A of the electronic components 13 and the heat sink portion 22H. However, in the case where the main body portions 13A are spaced from the heat sink portion 22H, interposition of the above-mentioned members therebetween may be unnecessary, and a gap may be present therebetween.

In addition, clips 17 having spring characteristics are disposed above the main body portions 13A, and the main body portions 13A are sandwiched between the clips 17 and the holder 15.

An upper-surface opening of the flow channel member 22, in which the circuit board 12 is housed, is closed by a cover portion 23 via a frame-shaped seal member (packing) S1.

Notably, in the present example, the cover portion 23 is also formed of a metal. Since the flow channel member 22 and the cover portion which surround the circuit board 12 are formed of a metal, an electromagnetic shielding effect of shielding the circuit board 12 from external noise can be obtained.

In addition, a frame-shaped seal member (packing) S2, a seal member (O-ring) S3, a flange holder 24, and a seal member (O-ring) S4 are disposed in this order in an opening of the tube portion 22t on the forward side (the leftward direction side in the Y-axis of FIG. 1).

The heater 11 extends through the seal members S2 and S3, the flange holder 24, and the seal member S4, and the surface of the flange portion 11B of the heater 11 on the rightward direction side in the Y-axis is in contact with the seal member S4.

Furthermore, on the opposite side of the flange portion 11B, a seal member (O-ring) S5, a heater base portion holder 25, a seal member (O-ring) S6, and a side cover 26 are disposed in this order.

The seal members S5 and S6 liquid-tightly seal opposite surfaces of the heater base portion holder 25, and the seal member S5 is in intimate contact with a proximal end of the heater 11. In addition, the flange portion 11B of the heater 11 is liquid-tightly sealed by the seal member S4. Furthermore, the flange portion 11B and the base portion of the heater 11 are supported in a cantilever fashion by the flange holder 24 and the heater base portion holder 25.

Notably, a temperature sensor 25b is inserted into a hole of the heater base portion holder 25 and is pressed and held by a forked portion of a clip 25a. The clip 25a is fixed to the heater base portion holder 25 by an unillustrated screw. A harness (not shown) for output transfer extends from the temperature sensor 25b and is connected to the circuit board 12.

Similarly, an outlet-side temperature sensor (not shown) is disposed in the flow channel member 22 to be located near the circuit board 12, and is fixed by a clip 27a having a shape similar to that of the clip 25a.

Meanwhile, an introduction port 26X, which is one end portion of the flow channel 21, is formed in the side cover 26 such that the introduction port 26X protrudes in the leftward direction in the Y-axis. The seal member S6 establishes a liquid-tight seal between the side cover 26 (its introduction port 26X) and the heater base portion holder 25. Thus, the introduction port 26X communicates with the flow channel 21 on the tube portion 22t side.

Furthermore, an opening of the flow channel member 22, which surrounds the outer side of the tube portion 22t, is closed by the side cover 26 via the seal member S2.

The heat medium heating apparatus 10 shown in FIG. 2 is assembled in the manner described above.

Next, a characteristic portion of the present invention will be described with reference to FIG. 3.

As shown in FIG. 3, the heat sink portion 22H having a mounting surface for the electronic components 13 on its upper side is connected to the outer boundary of the flow channel 21 (the tube portion 22t) and is formed integrally with the flow channel member 22.

By virtue of such a configuration, the heat generated by the electronic components 13 can be transferred from the heat sink portion 22H formed of a metal to the heat medium M in the flow channel 21, whereby the efficiency of heat radiation from the electronic components 13 can be increased.

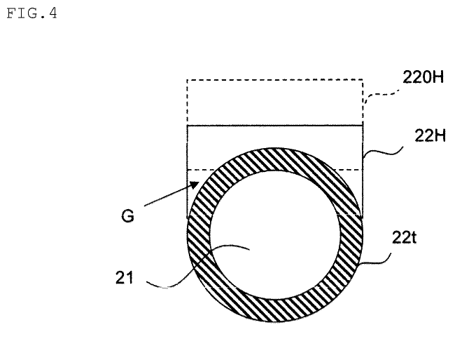

In the present example, as shown in FIG. 4, the flow channel 21 has a circular cross section, and the heat sink portion 22H is connected to the tubular outer boundary of the flow channel 21 (the tube portion 22t). Notably, FIG. 4 is a cross-sectional view of the flow channel 21, taken perpendicularly to the view of FIG. 3.

By virtue of such a configuration, since the flow channel 21 (the tube portion 22t) has a circular cross section, the heat medium M can smoothly flow through the flow channel 21. In addition, since the heat sink portion 22H is connected to the outer boundary of the flow channel 21 (the tube portion 22t) such that the heat sink portion 22H constitutes a portion of the outer boundary, the height (distance) of the heat sink portion 22H from the flow channel 21 (the tube portion 22t) can be reduced, whereby the size of the heat medium heating apparatus 10 can be reduced. In addition, the area of contact between the heat sink portion 22H and the flow channel 21 can be increased.

Notably, the flow channel 21, which has a “circular” cross section, is not required to have a constant diameter over the entire length of the flow channel 21. For example, the diameter of the flow channel 21 may decrease toward one side in the longitudinal direction, or may decrease and increase repeatedly along the longitudinal direction.

The phrase “connected to the tubular outer boundary of the flow channel 21” means that gaps G are not present between the heat sink portion 22H and the outer boundary of the flow channel 21 (the tube portion 22t).

In contrast, in an assumed case where a heat sink portion 220H is formed such that gaps G are provided between the heat sink portion 220H and the outer boundary of the flow channel 21 (the tube portion 22t) (see a broken line in FIG. 4), since the height (distance) of the heat sink portion 220H from the flow channel 21 becomes large, the size of the heat medium heating apparatus 10 increases. In addition, since the area of contact between the heat sink portion 220H and the flow channel 21 decreases in regions where the gaps G are provided, the efficiency of heat radiation from the electronic components 13 is poor as compared with the case where the gaps G are not present.

In the present example, as shown in FIG. 3, the flow channel 21 has the shape of a tube extending in the longitudinal direction L, and the diameter of the flow channel 21 increases along the flow direction F of the heat medium M in the longitudinal direction L.

By virtue of such a configuration, air bubbles produced in the heat medium M as a result of heating by the heater 11 become more likely to flow in the flow direction F and be discharged to the outside (the discharge port 22Y) from a diameter increased portion of the flow channel 21. As a result, it is possible to prevent the air bubbles from staying in the flow channel 21, which would otherwise result in heating by the heater 11 with no liquid.

Notably, as described later, in the present example, the heater 11 has a through hole 11H, and the heat medium M flows through the through hole 11H. However, the “flow channel 21″ refers to a space surrounded by the flow channel member 22 (the tube portion 22t). Namely, in the present example, the ”flow channel 21″ is a region between the inner surface of the tube portion 22t and the outer surface of the heater 11.

Accordingly, the flow direction F of the heat medium M in the “flow channel 21” is the flow direction between the inner surface of the tube portion 22t and the outer surface of the heater 11 and is a direction toward the leftward direction side in the Y-axis of FIG. 3. The diameter of the flow channel 21 increases toward the leftward direction side in the Y-axis of FIG. 3, which means that “the flow channel 21 increases in diameter along the flow direction F of the heat medium M.”

In the present example, as shown in FIG. 3, the heater 11 extends in an axial direction AX and has the through hole 11H along the axial direction AX. The heat medium M introduced into the through hole 11H through its one end (on the leftward direction side in the Y-axis of FIG. 3) flows out to the outer surface side of the heater 11 through the other end 11e of the through hole 11H. Subsequently, the heat medium M reverses its flow direction at the inner wall surface of the flow channel 21 and flows along the outer surface of the heater 11 toward the opposite side in the axial direction AX (toward the rightward direction side in the Y-axis of FIG. 3).

A corner portion 21e of the inner wall surface of the flow channel 21, which corner portion faces the other end 11e of the through hole 11H, is curved.

By virtue of such a configuration, when, after having flowed out to the outer surface side of the heater 11 from the other end 11e side of the through hole 11H, the heat medium M reverses its flow direction at the inner wall surface of the flow channel 21, the heat medium M smoothly flows along the curved corner portion 21e, whereby the efficiency of heat radiation from the electronic components 13 via the heat medium M can be further increased.

In the present example, the axial direction AX is parallel to the longitudinal direction L. However, no limitation is imposed on the relation between the axial direction AX and the longitudinal direction L, and the axial direction AX and the longitudinal direction L may intersect each other.

In the present example, the heater 11 has a circular cross section.

By virtue of such a configuration, the heat medium M smoothly flows along the outer surface of the heater 11, and thus, the efficiency of heat radiation from the electronic components 13 via the heat medium M cab be further increased.

It should be understood that the present invention is not limited to the above embodiment and incorporates various modifications and equivalents within the idea and the scope of the present invention.

In the above-described embodiment, the heater 11 is a ceramic heater. However, the heater 11 may be a PTC heater or a sheath heater.

In the above-described embodiment, the heater 11 has a circular tubular shape. However, the shape of the heater may be changed as appropriate.

No limitation is imposed on the cross-sectional shape of the flow channel.

### DESCRIPTION OF REFERENCE NUMERALS

10 heat medium heating apparatus
11 heater
11H through hole
11e other end of the through hole
12 circuit board
13 electronic component
21 flow channel
21e corner portion of the inner wall surface of the flow channel
22 flow channel member
22H heat sink portion
M heat medium
L longitudinal direction
AX axial direction

What is claimed is:

1. A heat medium heating apparatus comprising:
a circuit board;
an electronic component disposed on the circuit board;
a flow channel member formed of a metal and having a flow channel through which a heat medium flows; and
a heater which is disposed in the flow channel and heats the heat medium, wherein
a heat sink portion is formed integrally with the flow channel member,
the heat sink portion being connected to an outer boundary of the flow channel and having a surface on which the electronic component is mounted.

2. A heat medium heating apparatus according to claim 1, wherein the flow channel has a circular cross section, and the heat sink portion is connected to the tubular outer boundary of the flow channel.

3. A heat medium heating apparatus according to claim 1, wherein
the flow channel has a tubular shape and extends in a longitudinal direction, and
the flow channel increases in diameter toward a side in the longitudinal direction toward which the heat medium flows.

4. A heat medium heating apparatus according to claim 1, wherein
the heater extends in an axial direction and has a through hole along the axial direction,
the heat medium introduced into the through hole through its one end flows out to an outer surface side of the heater through the other end of the through hole, reverses its flow direction at an inner wall surface of the flow channel, and flows along an outer surface of the heater toward an opposite side in the axial direction, and
a corner portion of the inner wall surface of the flow channel, which corner portion faces the other end of the through hole, is curved.

5. A heat medium heating apparatus according to claim 1, wherein the heater has a circular cross section.
